(19) United States
(12) Patent Application Publication
(10) Pub. No.: US 2002/0144841 A1
(43) Pub. Date: Oct. 10, 2002

(54) High current SMD jumper

(75) Inventors: Guichao Hua, Edison, NJ (US); Yi Jiang, Zhijiang (CN)

Correspondence Address: OSTROLENK FABER GERB & SOFFEN, 1180 AVENUE OF THE AMERICAS, NEW YORK, NY, 100368403

(73) Assignee: Bel-Fuse, Inc.

(21) Appl. No.: 10/117,863

(22) Filed: Apr. 4, 2002

(30) Foreign Application Priority Data
Apr. 10, 2001 (CN) 01238814.9

(51) Int. Cl. H05K 7/06

(52) U.S. Cl. 174/261

(57) ABSTRACT

An SMD jumper for connection to a conductive trace on a printed circuit board, includes a conductive jumper element having a cross-sectional area substantially greater than that of the trace and at least two conductive terminals for connecting the jumper element to the trace. A single jumper element may be used or the jumper element may include at least two conductive layers separated by an insulator layer.

### BACKGROUND OF THE INVENTION

The present invention relates to power supplies and, in particular, to SMD (Surface Mounted Device) jumpers which conduct high current in low voltage DC-DC converters.

The ever-increasing demands for fast and more efficient data processing have prompted a significant development in the area of logic integrated circuits (ICs). It is expected that next generation of fast speed ICs will require power supplies with voltages in the range of 1V-2V. High power at low voltage is usually associated with high current. At the same time, as overall system sizes have continued to decrease, smaller size power supplies are required. This generally requires an increase in frequency of DC/DC power supplies, i.e., DC/DC converters, such as switching mode power supplies (SMPS). Confronted with these serious challenges, the technology of conventional SMPS converters must be improved.

Generally speaking, the components in power supplies are connected by copper traces of a printed circuit board (PCB). The DC power loss PDC of current in the copper traces are given by:

P_{DC}=I²_{DC}·R_{DC} (1)

where I_{DC} is the DC component of current and R_{DC} is the DC resistance of the copper trace. Clearly, P_{DC} is proportional to the square of the I_{DC}. Usually, the common method to reduce P_{DC} is to increase the thickness of the copper traces to decrease their resistance, but this will increase the manufacture cost of the PCB. Limited by the current manufacture techniques, copper traces on one side of the PCB are generally of the same thickness. However, as the current going through the control circuit is low, it is unnecessary and a waste to increase the thickness of the copper traces in the control circuit.

To reduce the size of an SMPS, the practical method is to increase the frequency of operation thereof. This, however, causes a skin effect and a proximity effect. Skin effect is caused by the high frequency current in the copper traces; proximity effect is caused by the high frequency current in adjacent copper traces. These two effects each increase the AC resistance of copper traces. And the higher the frequency the more distinct the effects. Also, the AC resistance in the copper traces where adjacent copper traces are close together is the highest when AC currents in adjacent copper traces run in opposite directions. The AC power loss P_{AC} of current in the copper traces is given by:

P_{AC}=I²_{AC}·R_{AC} (2)

where I_{AC} is the AC component of the current and R_{AC} is the AC resistance of copper traces. R_{AC} is larger than R_{DC} in the copper traces of high frequency converters, which means that AC power loss accounts for a considerable portion of the total loss of copper traces.

This invention discloses a novel SMD jumper that reduces total resistive loss of copper traces without increasing the thickness of copper traces in PCB.

### SUMMARY OF THE INVENTION

It is an object of the present invention to provide an SMD jumper for connection to a conductive trace on a printed circuit board, in accordance with one aspect of the present invention, includes a conductive jumper element having a cross-sectional area substantially greater than that of the trace, and at least two conductive terminals for connecting the jumper element to the trace.

Advantageously, the SMD jumper may further include a plurality of upstanding fins on a top surface of the conductive jumper element to facilitate cooling.

In accordance with another aspect of the invention, an SMD jumper for connection to an external circuit includes a jumper element which includes first and second conductive layers separated by an insulator layer, each of the jumper elements being conductive and having a cross-sectional area substantially greater than that of the conductive traces, at least a first pair of conductive terminals for connecting the first conductive layer to the external circuit, and at least a second pair of conductive terminals for connecting the second layer to the external circuit.

The SMD jumper, in accordance with this aspect, may have the conductive layers and insulating layers arranged horizontally or vertically with respect to each other.

The external circuit may include a pair of adjacent conductive traces on a printed circuit board in which case the first pair of conductive terminals connect the first conductive layer in parallel with a first one of the adjacent conductive traces and the second pair of conductive terminals connect the second layer in parallel with the second one of the adjacent copper traces.

In accordance with another aspect of the invention, an SMD jumper includes a plurality of alternating conductive layers and insulator layers for physically and electrically separating the conductive layers, the layers being arranged in a vertical array, first and second conductive pins for connecting first and second ones of the plurality of conductive layers to each other and to an external circuit, and third and fourth conductive pins for connecting third and fourth ones of the plurality of conductive layers to each other and to an external circuit.

The external circuit may comprise a single conductive trace on a printed circuit board in which case the first, second, third and fourth pins are physically and electrically connected to the single trace or, the external circuit may include first and second adjacent conductive traces on a printed circuit board in which case the first and third conductive pins physically and electrically connect the interconnected first and second conductive layers to the first trace and the second pair of conductive pins physically and electrically connect the third and fourth conductive layers to the second one of the traces.

Preferably, each layer has a hole through which one of the first, second, third or fourth pins pass, each pin passing through one hole in each of the layers, and the holes in a layer which are not to be physically or electrically connected by a pin, are made larger in cross-section than the pin so that the pin does not contact that hole and the holes, which are to be physically and electrically connected to a pin, are made substantially the same cross-section size as the pin so that the pin substantially contacts that hole.

In accordance with still another aspect of the invention, an SMD jumper includes a vertical array of first, second, third and fourth conductive layers and first, second and third insulator layers, the first and second conductive layers being separated by the first insulator layer, the second and third conductive layers being separated by the second insulator layer and the third and fourth conductive layers being separated by the third insulator layer, first and second conductive pins connecting the first conductive layer and the third conductive layers to each other; and third and fourth conductive pins connecting the second and fourth conductive layers to each other.

Advantageously, in all embodiments, a top surface of the array of the jumper and terminals for connecting the jumper to an external circuit are covered with a solder paste.

### BRIEF DESCRIPTION OF THE DRAWING(S)

Other features and advantages of the present invention will become apparent from the following description of the invention which refers to the accompanying drawings, wherein:

FIGS. 1(a), 1(b) and 1(c) are a perspective view, an end view and a plan view, respectively, of a first embodiment of an SMD jumper in accordance with the present invention;

FIG. 2 is a perspective view of a second embodiment of an SMD jumper in accordance with the present invention in which the surface of the jumper is increased;

FIG. 3 is a perspective view of a third embodiment of an SMD jumper in accordance with the present invention to reduce AC resistance in adjacent copper traces;

FIG. 4 is a perspective view of a fourth embodiment of an SMD jumper in accordance with the present invention to reduce AC resistance in adjacent copper traces;

FIG. 5 is a partially exploded perspective view with portions broken away of the embodiment of FIG. 4;

FIG. 6 is an exploded perspective view of the conductive and insulative layers of the embodiment of FIG. 4;

FIGS. 7(a) and 7(b) are perspective views, respectively, illustrating an application of the fourth embodiment to a single trace; and

FIGS. 8(a) and 8(b) are perspective and plan views, respectively, illustrating an application of the fourth embodiment to adjacent traces.

### DETAILED DESCRIPTION OF EMBODIMENTS OF THE INVENTION

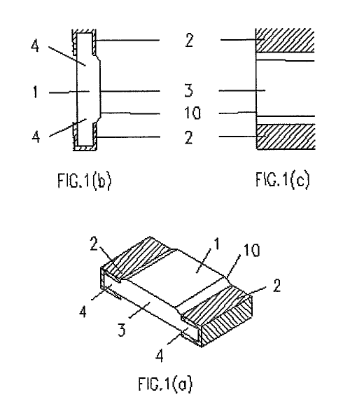

FIG. 1 shows a first embodiment of an SMD jumper 10 which includes a main jumper element 1 made of a conductive metal, such as copper, and two or more terminals 4 extending laterally therefrom which are also made of a conductive material, such as copper, and, preferably, are coated with a solder paste to facilitate soldering of the jumper 10 to a copper trace, i.e., conductor, on a PCB (Printed Circuit Board) (not shown). The main jumper element 1 is substantially thicker than the copper trace. For example, the thickness of the main jumper element 1 may be at least twice the thickness of the copper trace. Advantageously, the top surface 3 of the main jumper element 1 is covered by a soldermask to prevent the main jumper element 1 from being soldered or covered with any soldering or other materials during processing of the PCB. Since the main jumper element 1 of the SMD jumper 10 is made of a metal conductor substantially thicker than the copper trace on the PCB, the resistance of the copper trace is reduced when the SMD jumper 10 is soldered onto the trace in parallel therewith.

FIG. 2 illustrates a second embodiment of an SMD jumper 20 which is similar to the embodiment in FIG. 1 in that it includes a main jumper element 1 covered with a soldermask 3 and two or more terminals 4, preferably covered with solder paste 2. The embodiment of FIG. 2 differs from the embodiment of FIG. 1 in that the top surface 3 of the main jumper element 1 includes a plurality of upstanding fins 8 to effectively increase the surface area of the top surface of the SMD jumper 20. This results in the heat sinking capacity of the SMD jumper 20 being increased, particularly when cooled in forced air.

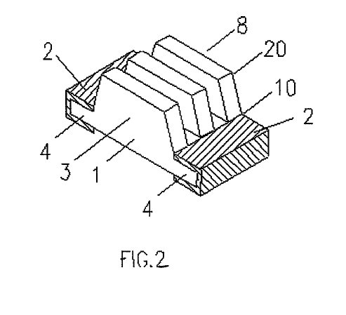

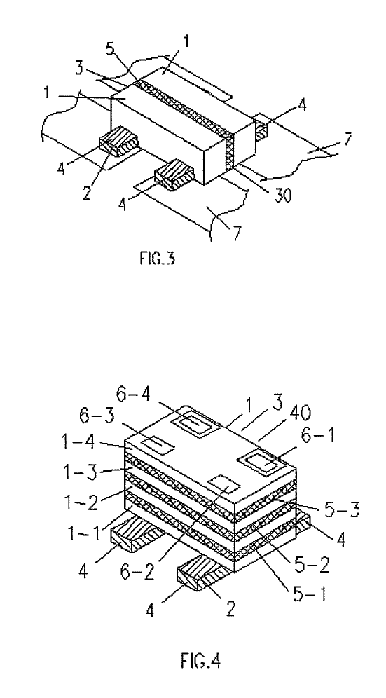

A third embodiment is shown in FIG. 3. In accordance with this embodiment an SMD jumper 30 includes a horizontally arranged array comprising a pair of main jumper elements 1, each of which is substantially thicker than the copper traces 7 of a PCB and is made of a conductive metal, such as copper. The main jumper elements 1 are separated by an insulator layer 5, which may be comprised of epoxy resin. Each of the main jumper elements 1 has at least two conductive terminals 4 extending laterally therefrom. Similar to the other embodiment, the top surfaces of the main jumper elements 1 and the insulator may be covered with a solder mask 3 and the terminals 4 may be covered with a solder paste.

In use, the SMD jumper 30 is connected to a pair of adjacent copper traces 7 such that each of the main jumper elements 7 is connected in parallel with a corresponding copper trace 7. This results in a decrease in the AC resistance of each of the traces 7. To understand why the AC resistance is decreased, it is first necessary to understand what happens when there is no SMD jumper between the two traces 7. Thus, suppose there are two parallel traces 7; when the currents in them are in opposite directions, they will attract each other. Consequently, the currents will be overwhelmingly denser on the inner side of each trace 7. This is called a proximity effect which, because of the concentration of current in a smaller cross-sectional area, results in an increase of AC resistance. When the SMD jumper 30 is connected between the two traces, the same phenomenon occurs between each of the jumper elements 1 and the trace 7 with which it is connected in parallel. This leads to a more balanced distribution of the current between the two traces 7 and the proximity effect is reduced. Additionally, the skin effect, which like the proximity effect results in concentration of the current flow near the surface of a conductor thereby increasing its AC resistance, is reduced. Accordingly, AC resistance, due to both proximity effect and skin effect, is reduced.

FIGS. 4, 5 and 6 illustrate a fourth embodiment of an SMD jumper 40 which further reduces AC resistance in adjacent copper traces. The embodiment illustrated in FIG. 4 includes a vertically arranged array of four conductive layers 1-1, 1-2, 1-3 and 1-4, separated by three insulating layers 5-1, 5-2 and 5-3.

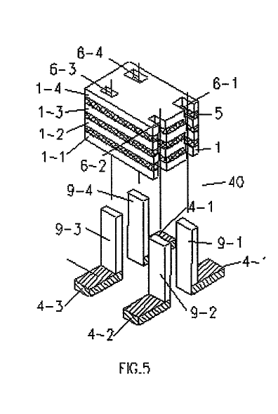

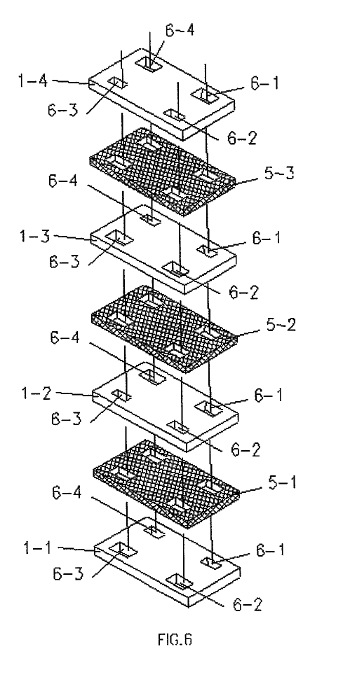

Referring to FIG. 5, the SMD jumper 40 includes four terminals, 4-1, 4-2, 4-3 and 4-4, having respective pins 9-1, 9-2, 9-3 and 9-4 for interconnecting the layers. More specifically, the pins 9-1 and 9-2 connect the layers 1-1 and 1-3 and the pins 9-3 and 9-4 connect the layers 1-2 and 1-4. In order to effect this interconnection, as best seen in FIG. 6, the holes 6-2 and 6-3 in the layers 1-1 and 1-3 are sized larger in cross-section then the pins 9-1 and 9-4 and the holes 6-1 and 6-4 in the layers 1-1 and 1-3 so that the pins 9-1 and 9-4 will only contact the holes 6-1 and 6-4, which are essentially the same cross-sectional size as the pins 9-1 and 9-4. Conversely, the holes 6-1 and 6-4 of the layers 1-2 and 1-4 are larger in cross-section than the pins 9-2 and 9-3 and the holes 6-2 and 6-3 in the layers 1-2 and 1-4 so that the pins 9-2 and 9-3 only contact the holes 6-2 and 6-3 in the layers 1-2 and 1-4, which are essentially the same cross-sectional size as the pins 9-1 and 9-4. The holes in the insulator layers 5-1, 5-2 and 5-3 are all larger in cross-section than the pins 9-1, 9-2, 9-3 and 9-4 so that the pins 9-1, 9-2, 9-3 and 9-4 do not contact any of the insulator layers 5-1, 5-2 and 5-3. Solder is used to more securely connect the pins to the holes that they are in contact with.

As a result of the above-described interconnection of the layers, the layers 1-1 and 1-3 are connected in parallel to the pins 9-1 and 9-4 and the layers 1-2 and 1-4 are connected in parallel to the pins 9-2 and 9-3.

This embodiment further reduces the proximity effect of the third embodiment (FIG. 3) because of the further balancing and distribution of current between the two adjacent traces and the four jumper elements. Similarly, this embodiment further reduces skin effect because the use of two jumper elements in parallel for each trace rather than a single element provides increased surface area.

Instead of being connected as shown in FIGS. 4, 5 and 6, holes 6-2 and 6-4 may be connected with layer 1-1 and layer 1-3; and the holes 6-1 and 6-3 may be connected with layer 1-2 and layer 1-4). As a result, the SMD jumper 40 could exchange the position of adjacent current, enhancing the flexibility of PCB layout.

Additionally, similar to the other embodiments, the SMD jumper may be covered, as shown in FIG. 4, with a solder mask 3 and the terminals 4-1, 4-2, 4-3 and 4-4 may be covered with a solder paste.

Further, although the SMD jumper 40 is shown as being comprised of four conductive layers alternately arranged with three insulator layers, the SMD jumper 40 may have as few as two conductive layers separated by a single insulator layer or may have greater than four conductive layers and greater than three insulator layers.

FIGS. 7(a) and 7(b) show the SMD jumper 40 connected to a single copper trace 7 to reduce AC resistance caused by skin effect in the copper trace 7.

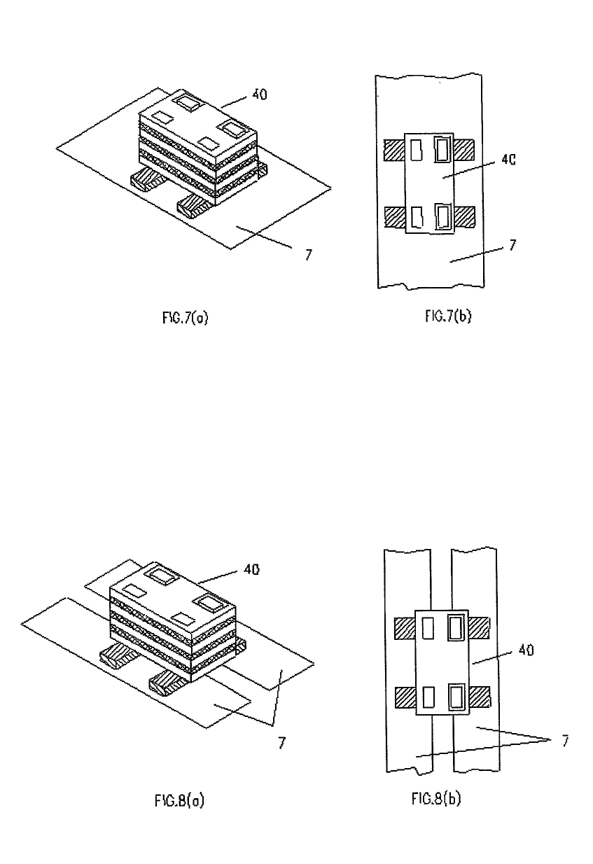

FIGS. 8(a) and 8(b) show the SMD jumper 40 connected to adjacent traces 7 to reduce AC resistance caused by both skin effect and proximity effect in the adjacent copper traces.

As should be apparent, in low voltage, high current DC-DC system, when the SMD jumper (10, 20, 30 or 40) is applied, power loss is reduced with insignificant additional cost.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed:

1. An SMD jumper for connection to a conductive trace on a printed circuit board, comprising:
a conductive jumper element having a cross-sectional area substantially greater than that of the trace; and
at least two conductive terminals for connecting the jumper element to the trace.

2. An SMD jumper according to claim 1, wherein a top surface of the conductive jumper element is covered with a soldermask and the terminals are covered with solder paste to facilitate soldering of the terminals to the conductive trace.

3. An SMD jumper according to claim 1, further including a plurality of upstanding fins on a top surface of the conductive jumper element.

4. An SMD jumper according to claim 3, wherein a top surface of the conductive jumper element is covered with a soldermask and the terminals are covered with solder paste to facilitate soldering of the terminals to the conductive trace.

5. An SMD jumper for connection to an external circuit, comprising:
a jumper element which includes at least first and second conductive layers separated by an insulator layer;
at least a first pair of conductive terminals for connecting the at least first conductive layer to the external circuit; and
at least a second pair of conductive terminals for connecting the at least second conductive layer to the external circuit.

6. An SMD jumper according to claim 5, wherein the conductive layers and insulating layers are arranged horizontally with respect to each other.

7. An SMD jumper according to claim 5, wherein the conductive layers and the insulating layers are arranged vertically with respect to each other.

8. An SMD jumper according to claim 5, wherein the external circuit includes a pair of adjacent conductive traces on a printed circuit board and wherein the first pair of conductive terminals connect the first conductive layer in parallel with a first one of the adjacent conductive traces and the second pair of conductive terminals connect the second layer in parallel with the second one of the adjacent copper traces.

9. An SMD jumper comprising:
a plurality of alternating conductive layers, adjacent conductive layers having an insulator layer therebetween for physically and electrically separating the adjacent conductive layers, the layers being arranged in a vertical array;
first and second conductive pins for connecting at least a first one of the plurality of the conductive layers to an external circuit; and
third and fourth conductive pins for connecting at least a second one of the plurality of the conductive layers to an external circuit

10. An SMD jumper according to claim 9, wherein the first and second conductive pins connect at least the first one of the plurality of conductive layers and at least a third one to each other and to the external circuit.

11. An SMD jumper according to claim 9, wherein the first and second conductive pins connect a first group of conductive layers, including the first one of the plurality of conductive layers, to each other and to the external circuit, and the third and fourth conductive pins connect a second group of conductive layers, including the second conductive layer, to each other and to the external circuit.

12. An SMD jumper according to claims 9, 10 or 11, wherein the external circuit comprises a single conductive trace on a printed circuit board and the first, second, third and fourth pins are physically and electrically connected to the single trace.

13. An SMD jumper according to claims 9, 10 or 11, wherein the external circuit includes first and second adjacent conductive traces on a printed circuit board and the first and third conductive pins are physically and electrically connected to the at least first trace and the third and fourth conductive pins are physically and electrically connected to the second one of the traces.

14. An SMD jumper according to claims 9, 10 or 11, wherein each layer has a hole through which one of the first, second, third or fourth pins pass, each pin passing through one hole in each of the layers.

15. An SMD jumper according to claim 14, wherein the holes in a layer which are not to be physically or electrically connected by a pin are made larger in cross-section than the pin so that the pin does not contact that hole and wherein the holes, which are to be physically and electrically connected to a pin are made substantially the same cross-section size as the pin so that the pin substantially contacts that hole.

16. An SMD jumper according to claim 15, wherein a top surface of the array of alternating conductive layers and insulator layers is covered with a soldermask, the pins are connected to terminals, and the terminals are covered with a solder paste.

17. An SMD jumper, comprising:
a vertical array of first, second, third and fourth conductive layers and first, second and third insulator layers, the first and second conductive layers being separated by the first insulator layer, the second and third conductive layers being separated by the second insulator layer and the third and fourth conductive layers being separated by the third insulator layer;
first and second conductive pins connecting the first conductive layer and the third conductive layer to each other; and
third and fourth conductive pins connecting the second and fourth conductive layers to each other.

18. An SMD jumper according to claim 17, wherein a top surface of the array of alternating conductive layers and insulator layers is covered with a soldermask, the pins are connected to terminals and the terminals are covered with a solder paste.
